(19) United States
(12) Patent Application Publication
(10) Pub. No.: US 2017/0287540 A1
(43) Pub. Date: Oct. 5, 2017

(54) CROSSPOINT ARRAY DECODER

(71) Applicant: Hewlett Packard Enterprise Development LP, Houston, TX (US)

(72) Inventors: Brent Buchanan, Palo Alto, CA (US); Amit S. Sharma, Palo Alto, CA (US); Gary Gibson, Palo Alto, CA (US); Erik Ordentlich, San Jose, CA (US); Naveen Muralimanohar, Santa Clara, CA (US)

(21) Appl. No.: 15/507,790

(22) PCT Filed: Sep. 25, 2014
(86) PCT No.: PCT/US2014/057364

§ 371 Date: Mar. 1, 2017

(51) Int. Cl. G11C 8/10; G11C 13/00

(52) U.S. Cl. CPC G11C 8/10; G11C 13/0023; G11C 13/0026; G11C 13/0028

(57) ABSTRACT

Example implementations disclosed herein can be used to decode memory elements in a crosspoint array. In one example implementation, a drain voltage is applied to a drain terminal of a field effect transistor switch for a selected row in the crosspoint array associated with the selected memory element. A bulk terminal of the field effect transistor switch for the selected row can be biased with a well voltage that is independent of the drain, source, or substrate voltages. In such examples, the gate terminal of the field effect transistor switch for the selected row can be driven with a gate voltage comprising the drain voltage and the well voltage. The drain voltage, the well voltage, and the gate voltage are selected to cause the field effect transistor switch for the selected row to operate as an ohmic switch.

### BACKGROUND

Crosspoint arrays are structures used to address multiple elements. For example, a crosspoint array can be used to address a collection of individual memory elements in a memory cell. Each memory element can be addressed using a specific configuration of the crosspoint array. Such crosspoint arrays can include parallel bitlines (e.g., columns) crossed by perpendicular wordlines (e.g., rows) with the switching material of the memory element placed between the wordlines and bitlines at every crosspoint. Such configurations of memory elements are referred to as crosspoint memory cells. Crosspoint array memory cells use various types of array decoder switches to selectively couple specific bitline-wordline pairs to appropriate stimulus signals (e.g., voltages or currents) to read, write, set, or form specific memory elements.

### BRIEF DESCRIPTION OF THE DRAWINGS

FIG. 1 is a schematic of a portion of a crosspoint memory cell in which examples of the present disclosure can be implemented.

FIG. 2 is a schematic of a subset of the decoder switches in a crosspoint array memory cell, according to various examples.

FIG. 3 is a schematic of example field effect transistor type decoder switches in a crosspoint array memory cell, according to various examples.

FIG. 4 illustrates potential sneak currents in a memory element in a crosspoint array memory cell addressed using field effect transistor type decoder switches, according to various examples.

FIG. 5 is a schematic of field effect transistor type decoder switches disposed in doped semiconductor wells, according to various examples.

FIG. 6 is a schematic of row and column field effect transistor type decoder switches disposed in doped semiconductor wells, according to various examples.

FIG. 7 illustrates example configurations of field effect transistor type decoder switches disposed in doped semiconductor wells, according to various examples.

FIG. 8 is a schematic of field effect transistor type decoder switches disposed in doped semiconductor wells with forward and back biasing, according to various examples.

FIG. 9 is a flowchart of a method for addressing a crosspoint array memory cell, according to various examples.

### DETAILED DESCRIPTION

Various example implementations described herein include crosspoint array decoders for efficiently decoding crosspoint memory arrays. Decoder switches in crosspoint array memory cells are used to apply stimulus voltages (e.g., set, reset, read+, read−, etc.) to a selected bit-cell. To apply the stimulus voltage, the decoder switches can tie both the selected row and column associated with the selected bit-cell to the appropriate voltages, and either isolate the unselected rows and columns from any voltages or tie some subset of the unselected rows and columns to bias voltages. In some implementations, the bias voltages can be different from the stimulus voltage applied to the selected rows and columns.

In the following detailed description of the present disclosure, reference is made to the accompanying drawings that form a part hereof, and in which is shown by way of illustration how examples of the disclosure can be practiced. These examples are described in sufficient detail to enable those of ordinary skill in the art to practice the examples of this disclosure, and it is to be understood that other examples can be utilized and that process, electrical, and/or structural changes can be made without departing from the scope of the present disclosure.

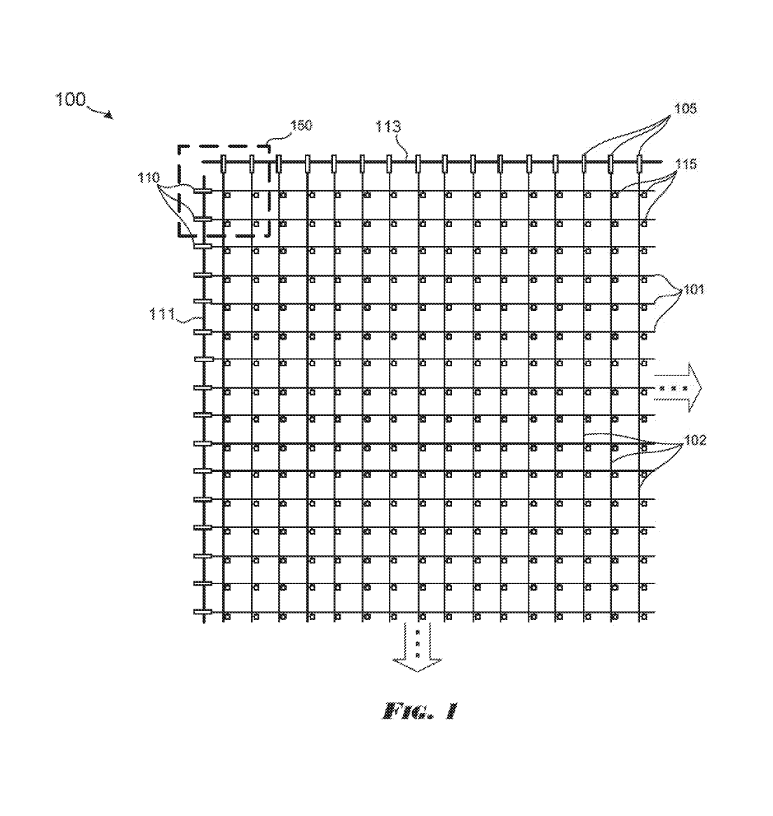

FIG. 1 depicts a portion 100 of a crosspoint array memory cell. While only the portion 100 of the particular example crosspoint array memory cell s shown, examples of the present disclosure can be scaled to apply to the entire crosspoint array memory cell. As shown, the crosspoint array memory cell can include multiple rows 101 and multiple columns 102 of conductor lines arranged in a grid or other crosshatch type pattern. For the sake of brevity and clarity, crosspoint array memory cells are often referred to herein simply as crosspoint arrays. Accordingly, examples of the present disclosure can be applied to addressing memory elements 115 as well as other devices disposed in crosspoint array type structures.

In various implementations, the rows 101 and columns 102 are disposed in isolated layers of a semiconductor device or package. At each crossover point, the rows 101 and columns 102 can be coupled to one another through a corresponding memory element 115. Each memory element 115 can include any volatile or non-volatile switching material to store one or more bits. Accordingly, as described herein, memory elements 115 can also be referred to as bit cells that can be set to one state or another to represent an “on” state or “off” state, otherwise referred to as a “1” or a “0” in binary.

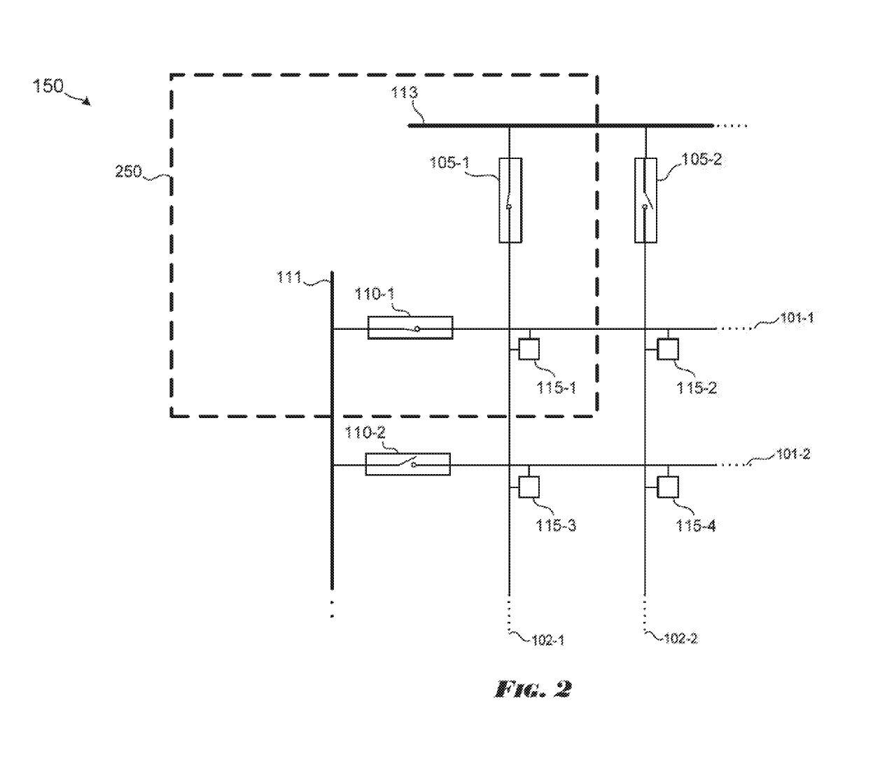

Specific memory elements 115 can be addressed by activating one or more corresponding row switching devices 110 and column switching devices 105. Addressing a particular memory element 115 may include closing the corresponding switching devices 110 and 105 to complete a particular electrical path to voltage supply lines 111 and 113 to apply stimulus voltages to one or more of the terminals of the memory elements 115. FIG. 2 depicts a detailed view of the section 150 of the portion 100 of the crosspoint array.

As shown in FIG. 2, memory element 115-1 can be addressed by activating (e.g., closing) row switching device 110-1 and column switching device 105-1 to couple corresponding row 101-1 and column 102-1 to the voltages supplied on voltage supply lines 111 and 113. Addressing a particular memory, such as memory element 115-1 in a crosspoint array is also referred to as decoding the crosspoint array. Accordingly, the row and column switching devices 110 and 105 are also referred to as “decoder switches”. In the configuration of section 150 depicted, row decoder switches 110-2 and column decoder switches 105-2, as well as other row column decoder switches not shown in FIG. 2, are deactivated (e.g., open).

However, because the voltages on voltage supply lines 111 and 113 may be applied to at least one terminal of unselected memory elements 115 (e.g., memory elements 115-2 and 115-3) through the selected row 101-1 and selected column 102-1, current can leak through the unselected memory elements 115 even though the corresponding row and column decoder switches are open. Example implementations of crosspoint array decoders according to the present disclosure can reduce or eliminate the undesired leakage current through unselected memory elements 115 and reduce the undesirable voltage drops across various types of decoder switching devices 110 and 105. Such implementations can thus increase the speed, sensitivity, and efficacy of reading from, writing to, and forming individual memory elements 115 in a memory cell.

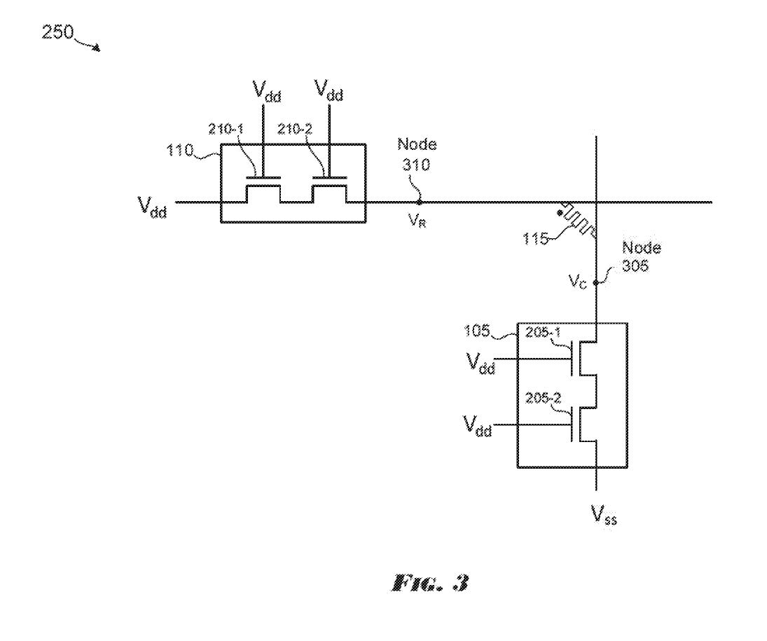

In various examples, decoder switching devices 105 and 110, which are also referred to herein as decoder switches, can be implemented using one or more field effect transistors (FETs). FIG. 3 illustrates an example implementation in which decoder switches 110 and 105 include FETs 210 and 205, such as NFETs, PFETs, and the like. Such FET type decoder switches 105 and 110 can be implemented to support current flow in either direction through the selected memory element 115 (i.e., the current path can be symmetrical). In the particular example configuration shown in FIG. 3, each decoder switch 105 and 110 includes two layers of decoding (e.g., FETs 205-1 and 205-2 and FETs 210-1 and 210-2), however, in other example implementations, each of the decoder switches 105 and 110 can include only one FET or can include more than two FETs.

Physical FETs are not perfect switches. Each FETs channel in a decoder switch will have some non-zero “on-resistance”, R_{On}. The resistance R_{On} of each FET 210 and 205 can cause corresponding voltage drops across the decoder switches 110 and 105 and reduce the available voltage that can be applied to the selected memory element 115. The voltage available to the memory element 115 is often referred to as “voltage headroom”. Accordingly, the voltage headroom in and between V_{R} and V_{C} at nodes 310 and 305 respectively can be lower than is optimal and may even limit the functionality and/or efficacy of the crosspoint array decoder for reading, writing, and setting memory elements 115, such as resistive memory elements (e.g., memristors).

Current flows through the selected memory element 115 when gates of FETs 205 in column decoder switch 105 (e.g., FETs on the Vₛₛ side of the serial stack) and gates of FETs 210 in row decoder switch 110 (e.g., FETs on the drain voltage or V_{dd} side of the serial stack) are driven with a gate voltage at or above the drain voltage, V_{dd}, as depicted in FIG. 3. Under such conditions, the voltage V_{dd} applied to the gate terminals of FETs 205 is greater than the voltage V_{c} applied to the drain of FET 205-1 by more than a threshold voltage, V_{T}, (where V_{T} is the gate-source voltage at which the transistor begins to conduct) so the FETs 205 will operate in what is referred to herein as the “linear region”. FETs are said to operate in their linear region when the operating voltages cause the FETs to behave much like a resistor, i.e., the channel current, I_{ds}, is linear with the drain-source voltage, V_{ds} (with V_{ds}=Rₒₙ·I_{ds}).

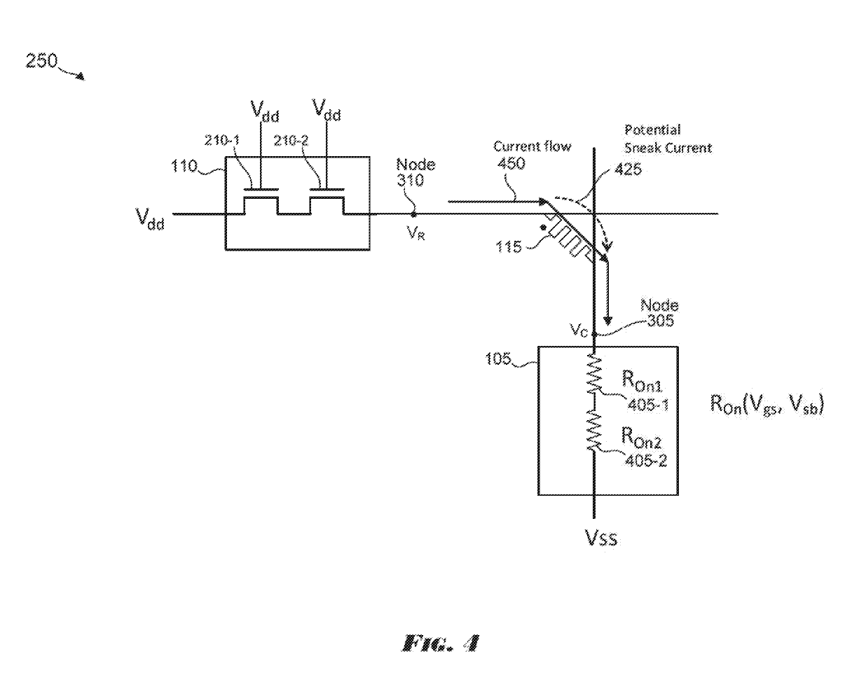

When FETs 205 are operated in the linear region, they operate as ohmic switches. The resistance of the FET channel, R_{On}, is a function of the gate-source voltage in excess of V_{T} (e.g., R_{On}(ΔV_{gs}), where ΔV_{gs}, known as the ‘excess gate voltage’, is equal to Vgs−V_{T}, and R_{ON} decreases with increasing ΔVgs) and in some example implementations can cause only minimal voltage drops (e.g., approximately 10 mV to 100 mV). When FETs 205 operate as ohmic switches, they can be treated as resistors 405 with corresponding resistances (e.g., R_{On1} and R_{On2}), as illustrated in FIG. 4. With low R_{On} values, little of the total headroom between V_{dd} and Vₛₛ is spent.

However, when the gates of the FETs 210 in the row decoder switch 210 are driven at V_{dd}, FETs 210-1 and 210-2 will operate as a source followers with very small excess gate voltages, ΔV_{gs}, and thus larger channel resistances, R_{On}. As source followers, source voltages of FETs 210-1 and 210-2 can be approximately V_{T} below their respective gate voltages. However, since the source-bulk voltages of both FETs 210-1 and 210-2 are large, the threshold voltages for FETs 210-1 and 210-2 is considerably larger than the case where V_{sb} is small or 0, as for FETs 205-1 and 205-2 when they operate as resistors 405-1 and 405-2. The combined effect can cause a significant voltage drop across row decoder switch 110, thus causing corresponding reduction in voltage V_{R} at node 310 that can be applied to the selected memory element 115. In some scenarios, V_{R} can be approximately 2V_{T} below V_{dd}. Under such operating conditions, the voltage headroom available to stimulate memory element 115 can be reduced by more than 1 V, thus reducing the efficacy and speed with which the memory element 115 can be read, written, and set.

To operate the FETs 210 in or closer to their linear operating mode, the gates of the FETs 210 can be driven higher. However, driving the gates of the V_{dd} side decoder FETs 210 above V_{dd} to force them into linear operation can be difficult because the gates may already be at the maximum voltage that can be used safely. Pushing the gate voltage above V_{dd} could potentially damage FETs 210. Implementations of the present disclosure include structures and methods for reducing the V_{T} and potentially allowing the gate voltage to increase safely above V_{dd} for the FETs 210 and/or FETs 205 by forming the bulk of the transistors in one or more isolated wells that can be independently biased.

Some example implementations include use of alternative configurations, structures, and components in standard processes to reduce V_{T} of the FETs 210 and 205. In standard bulk planar CMOS processes, the bulk of FET 210 and 205 can be a common doped semiconductor. In some implementations, in which the FETs 205 and 210 are NFETs, the bulk structure of the FETs can include a P-type doped semiconductor material (e.g., silicon). In such examples, the bulks of decoder NFETs 205 and 210 can be the same structure that is biased to Vₛₛ. According to various implementations of the present disclosure, the V_{T} of FETs 210 and 205 can be altered by forming the FETs with isolated bulks that can independently biased.

In various example implementations, decoder switches 105 and 110 can be full pass gates by using PFETs instead of NFETs. PFETs require greater physical widths for the gate to handle the same current and voltage drops as smaller form factor NFETs. Because the composition and structure of PFETs are larger than that of NFETs, using PFETs instead of NFETs results in larger decoder switches than when NFETs are used. Using PFETs may also require a well of N type doped silicon (e.g., an N-well) to correctly bias the bulk because in many standard CMOS processes in which the substrate is a P type semiconductor.

In addition to the potential complexities associated with operating FETs 210 and 205 in their respective saturation and/or linear regions, aspects of the physical structure of the crosspoint array 100 can also cause unwanted sneak currents 425, as illustrated in FIG. 4. Potential sneak currents 425 can occur when unselected memory elements 115 that are on the same row or column as the selected memory element 115 draw some current due to the voltage drop across the unselected memory elements 115. It is desirable to avoid sneak currents in unselected memory elements 115 to increase the speed with which the selected memory elements 115, such as resistive memory elements, can be read from, written to, or set.

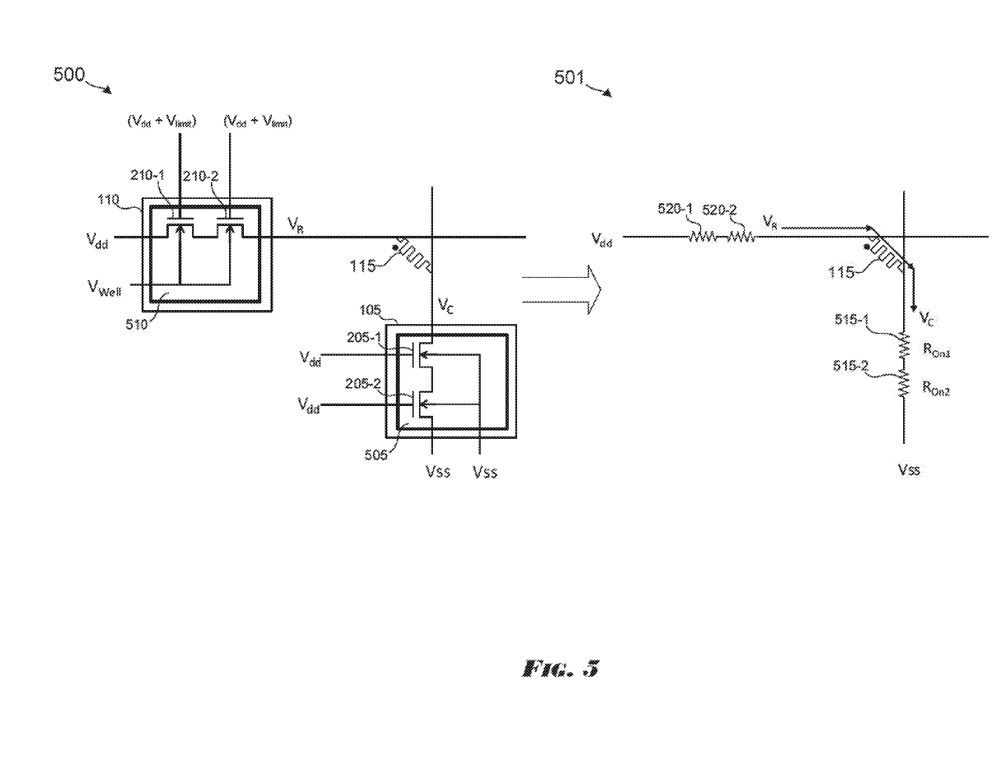

Various example implementations that can help reduce undesirable voltage drops and sneak current can include locating row FET type decoder switches 110 in one or more isolated wells and the column FET type decoder switches 110 in one or more other isolated wells. FIG. 5 illustrates one such example.

As shown in FIG. 5, FETs 210 and 205 in the decoder switches 110 and 105 are located in wells 510 and 505 of doped semiconductor material, respectively. In implementations in which NFETs are used, the well may be a P-well. In implementations in which PFETs are used, the well may be an N-well. For the sake of clarity, FIG. 5 is described in reference to an example implementation in which FETs 210 and 205 are NFETs and wells 510 and 505 are P-wells. In such implementations, the bulk terminal of NFETs 210 on the V_{dd} side of the serial stack (e.g., in the decoder switches 110) can be biased separately from the bulk terminals of NFETs 205 on the Vₛₛ side of the serial stack (e.g., in the decoder switches 105) to a voltage that will reduce or eliminate the increase in V_{T} from high source-bulk voltages. Accordingly, the P-well 510 can be treated as its own high-voltage region so the voltages applied to the gate terminals of NFETs 210 can be raised to V_{dd} plus some upper limit voltage (Vₗᵢₘᵢₜ), thus driving their corresponding R_{On} to values comparable to those of the NFETs 205 in the column decoder switches 105 (e.g., on the Vₛₛ side of the serial stack).

As shown in FIG. 5, when the wells 510 and 505 in schematic 500 are biased with voltages near but no higher than the lowest voltage in the respective well (e.g., the lowest voltage in the available domain of voltages), all of the NFETs 210 and 205 behave as ohmic switches, as depicted in schematic 501. As shown, when the well 510 (e.g., the bulk of FETs 210-1 and 220-2) is biased to a voltage V_{well} and the wall 505 (e.g., the bulk of FETs 205-1 and 205-2) is biased to Vₛₛ, the FETs 210 and 205 behave as resistors 520 and 515, having R_{On} values such that V_{R} an V_{C} are close to V_{dd} and Vₛₛ, respectively. Since the circuit show in schematic 501 is symmetric, current can flow in either opposite direction by mirroring the conditions such that the formerly Vₛₛ side of the stack (e.g., decoder switch 210) becomes the V_{dd} side of the stack (e.g., decoder switch 205).

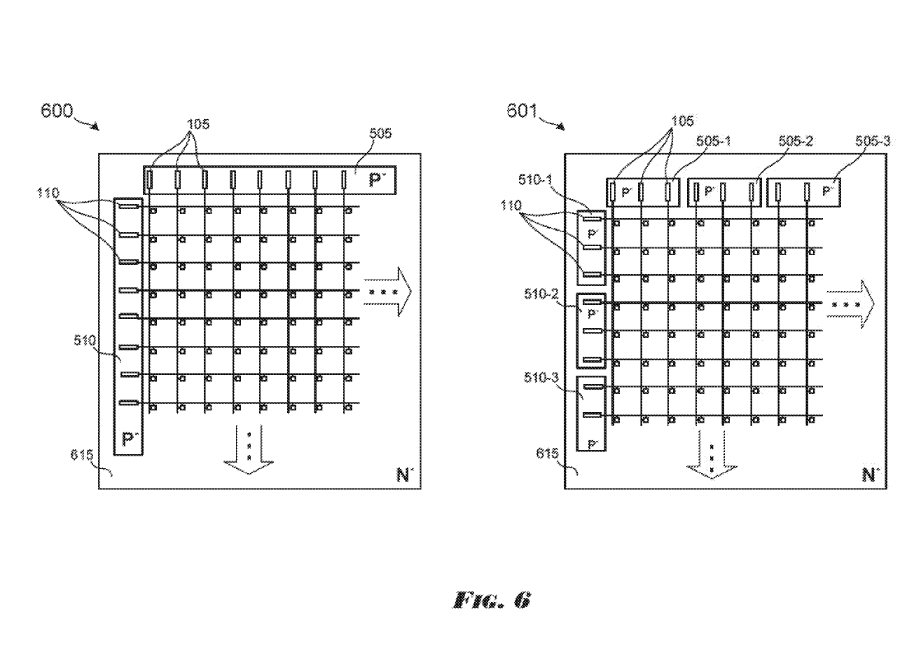

FIG. 6 depicts example implementations 600 and 601 that illustrate how the FETs of decoder switches 110 and 105 of a crosspoint array can be disposed in wells 510 and 505 so as to be isolated from one another, the substrate 615, and other components of the crosspoint array. In example 600, P⁻ type wells 510 and 505 are formed in an N⁻ type substrate 615. In one specific example, NFET type column decoder switches 105 are formed in a single P⁻ type well 505 and NFET type row decoder switches 110 are formed in another single P⁻ type well 510. In example 601, the NFET type row decoder switches 110 are formed in a multiple P⁻ type wells 510 and the NFET type column decoder switches 105 are formed in multiple P⁻ type wells 505. Example 601 shows each of the multiple P⁻ type wells 510 and 505 include three of the multiple NFET type decoder switches 110 and 105. However, in accordance with other example implementations of the present disclosure, the isolated P⁻ type wells 510 and 505 may also include more or fewer than three of the NFET type decoder switches 110 and 105. While the wells 510 and 505 of examples 600 and 601, and others, are shown and described as P⁻ type wells, in other examples, these wells can be N⁻ type wells and the FET type decoder switches 110 and 105 can include PFETs, as described in more detail herein.

The isolated P⁻ type wells 510 and 505 can be formed by starting with N⁻ type substrate 615. In alternative examples, the wells can be P⁻ type wells formed in N⁻ type wells that are formed in a P⁻ type substrate. Accordingly, decoder switches 110 and 105 can be implemented as PFETs within N⁻ type wells to obtain well isolation and control. Such PFET implementations are useful in substrates in which NFET mobility is not greater than PFET mobility. However, NFETs can offer the benefit of allowing for smaller circuit layout footprints. The reduction in crosspoint array size allows for greater economy with respect to die density and fabrication capacity.

With the well biases under individual control, back-biasing is also possible. The voltage of each well, and subsequently the bulk terminal of the FETs 210 and 205 can be used to adjust the threshold voltage, V_{T}, as needed. For example, the bias voltage on the bulk of the FETs 210 and 205 can be increased to reduce leakage, or decreased to reduce R_{On}. Back-biasing the wells can also be used as a means of adjusting V_{R} and V_{C}. The ability to make adjustments to V_{R} and V_{C} are useful in design or operation situations in which adjustments via changes in V_{dd} are impractical, impossible, or otherwise undesirable.

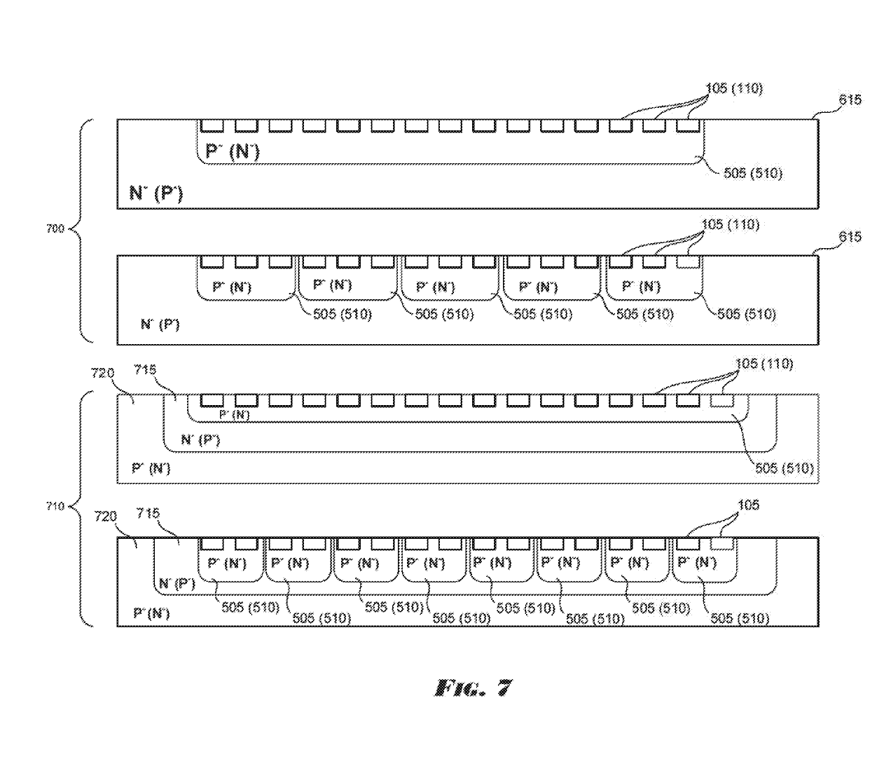

FIG. 7 depicts cross sections of specific example implementations 700 and 710 in which the FET based decoder switches 105 or 110 are formed in isolated wells. In examples 700, the FET based decoder switches 105 for the columns of the crosspoint array may be disposed in one or more isolated wells and decoder switches 110 for the rows of the crosspoint array can be disposed in one or more other isolated wells 510 formed in the substrate 615. In examples 700 and 710, the substrate can include an N⁻ type substrate or a P⁻ type substrate. Accordingly, the isolation wells 505 can include correspondingly different P⁻ type wells or N⁻ type wells 505.

Example 710 depicts a cross section of an example implementation in which the semiconductor and/or dopant type of well 505 in which the FET type decoder switches 105 and 110 are disposed is the same as the substrate 720. In one specific example, the wells 505 are a P⁻ type semiconductor and the substrate 720 is also a P⁻ type semiconductor. To isolate the P⁻ type wells 505 from the P⁻ type substrate 720, the P⁻ type wells 505 can be disposed in an intermediate N type well 715.

As described herein and shown in example 601 of FIG. 6, subsets of column and/or row decoder switches can be located in different wells to enable biasing of the corresponding rows and columns of the array to different voltages. Subsets of the column and/or row decoder switches can include as few as one decoder switch 110 and 105, and as many as all the decoder switches 110 and 106.

Grouping subsets of decoder switches 110 and 105 into corresponding isolated wells provides the ability to localize the control of decoder switches 110 and 105 of both the selected and unselected rows and columns to improve read, write, and set performance of the crosspoint array. For example, decoder switches 110 and 105 in wells 510-1 and 505-1 can be biased independently of other switches 110 and 105 in wells 510-2, 510-3, 505-2, and 505-3. In such implementations, the decoder switches 110 and 105 for the unselected rows and columns can be biased to avoid leakage or sneak currents into unselected memory elements 115.

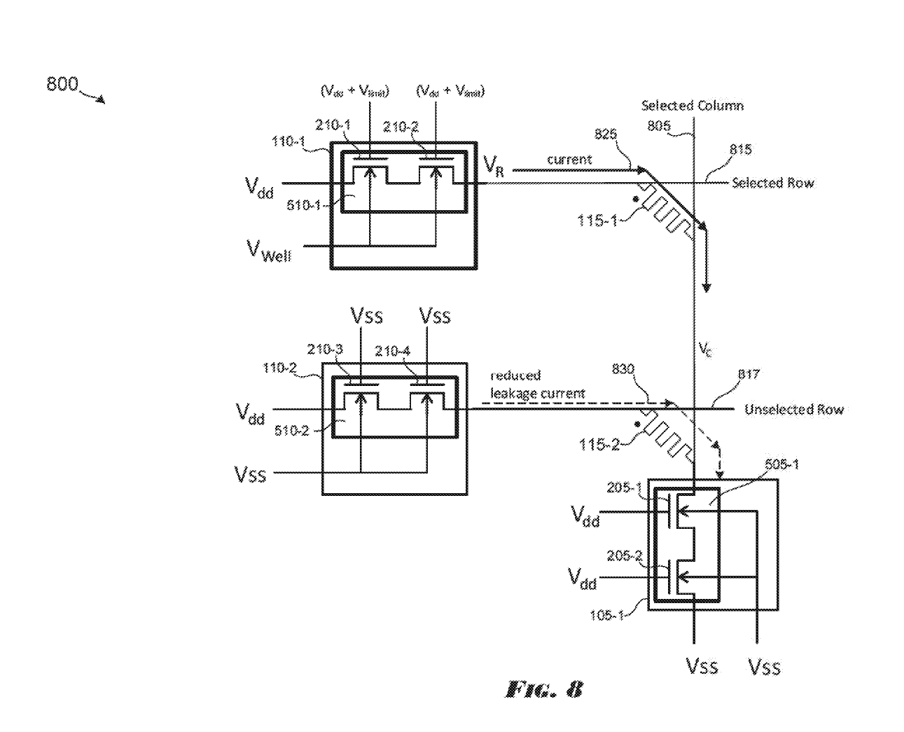

FIG. 8 illustrates example operation 800 of FET based decoder switches 110 and 105 to apply stimulus voltages to memory elements in a crosspoint array according to a specific implementation of the present disclosure. The isolated wells 510-1 of FET based decoder switch 110-1 for selected row 815 (e.g., the bulk of FETs 210-1 and 210-2) can be biased to a voltage V_{well} to lower the corresponding threshold voltages, V_{T}, of FETs 210-1 and 210-2. Lower threshold voltages in FETs 210-1 and 210-2 can result in correspondingly smaller R_{On} values and smaller voltage drops across the selected row decoder switch 110-1. Accordingly, V_{R} will be closer to V_{dd}, thus providing more voltage headroom for applying stimulus voltages to and larger current 825 through selected memory element 115-1.

In some implementations, the isolated well 510-2 of FET based decoder switch 110-2 for unselected row 817 can be biased to Vₛₛ or another voltage to increase the threshold voltage, V_{T}, of corresponding FETs 210-3 and 210-4. Increasing V_{T} of the FETs 210-3 and 210-4 in the unselected row 817 can reduce or eliminate leakage current 830 through unselected memory elements 115-2. This also allows for lower V_{T}, and consequently lower R_{On}, in FETs 210-1 and 210-2 in the selected row 815. Low R_{On} for the selected row 815 and low or no leakage current 830 through FETs 210-3 and 210-4 increases the performance of the crosspoint array.

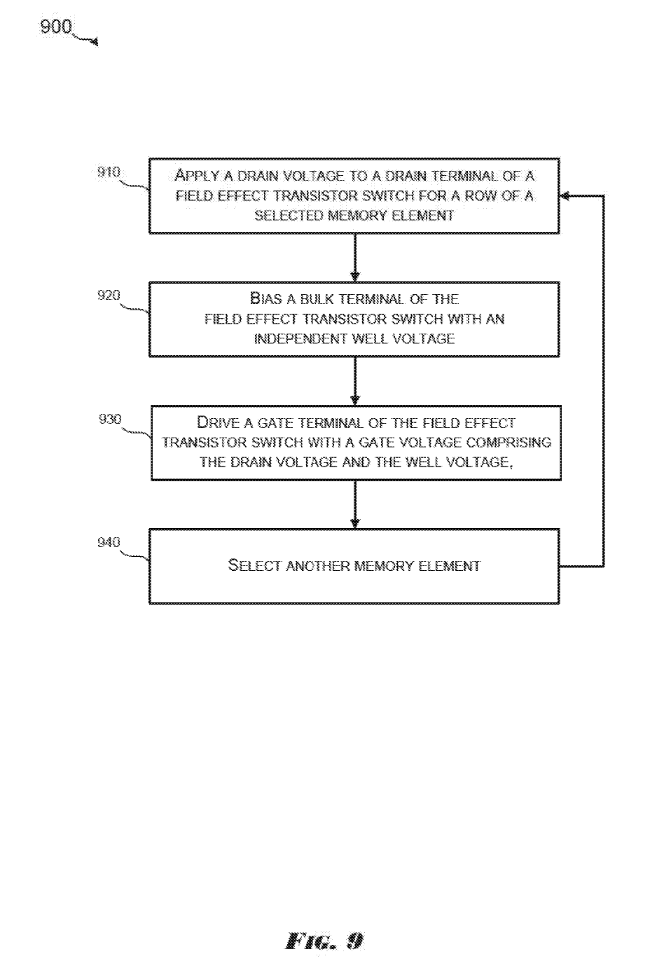

FIG. 9 is a flowchart of a method 900 of operating FET based decoder switches to apply stimulus voltages to memory elements 115 in a crosspoint array according to various implementations of the present disclosure. The crosspoint array can include multiple FET based decoder switches for selectively coupling selected rows and columns to stimulus voltages to read, write, set, or form memory elements 15. At box 910, method 900 can include applying a drain voltage to a drain terminal of one or more of the FET based switches corresponding to the row of a selected memory element 115. In such embodiments, the drain terminal of the FET based decoder switch may be coupled to one or more drain terminals of the one or more FETs in the switch. The drain voltage, also referred herein as V_{dd}, may be chosen based on the voltage and/or current requirements associated with the specific type of memory elements 115 in the array. For example, the drain voltage may be set to read, write, set, or form resistive nonvolatile memory elements 115, such as memristors.

At box 920, the bulk terminal or terminals of the FETs 210 in the FET based decoder switch 110 can be biased with a well voltage that is different from the voltage applied to the substrate. The well voltage can also be different from the drain voltage, the source voltage, and/or gate voltage. In one embodiment, biasing the bulk terminals of the FETs 210 can include biasing an isolated well 510 in which one or more of the FET based switches 210 are formed. Accordingly, biasing the isolated well 510 can include biasing the bulk terminal of the FETs 110 for the selected raw end possibly other rows that share the isolated well 510. Thus, biasing the isolated well 510 associated with the selected row can also include applying a well voltage that is different from the voltage to which one or more other isolated wells 510 associated with unselected rows are biased. In addition, biasing the isolated well 510 can include applying a well voltage that is different from the voltage to which one or more other isolated wells 505 associated with FET based decoder switches 105 for the selected and/or unselected columns are biased. In one example, the well voltage is lower than or equal to the drain voltage minus the voltage drop across the FET based decoder switch 110 given a particular on-resistance. The well voltage can be the lowest voltage in a domain of voltages associated with the crosspoint array and/or the FET based decoder switch 110. Similarly, the voltage to which the isolated wells of the FET based decoder switches 105 for the columns can be the lowest voltage in a domain of voltages associated with the FETs 205 and/or the FET based decoder switches 105.

At box 930, the gate terminal of the FET based decoder switch 110 for the selected row can be driven with a gate voltage comprising the drain voltage and the well voltage to provide a low, if not the lowest, on-resistance and minimal voltage drop. The resulting voltage (e.g., drain voltage minus the voltage drop) can then be applied as a stimulus voltage to the selected memory element 115.

At box 940, another memory element 115 can be selected. The action in boxes 910 through 930 can then be repeated for that memory element 115.

According to the foregoing, examples disclosed herein enable FET based decoder switches to provide more of the available voltage (e.g., the drain voltage) to the selected memory element 115 instead of losing it across decoder FETs, making more voltage available for forming, switching, and reading the selected memory elements 115.

These and other variations, modifications, additions, and improvements may fall within the scope of the appended claims(s). As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

What is claimed is:

1. A crosspoint array decoder comprising:
a first terminal to supply a first voltage;
a second terminal to supply a second voltage;
a plurality of row switching devices disposed in a first doped semiconductor well and coupled to the first terminal, each of the plurality of row switching devices coupled to a corresponding row line in a plurality of row lines in a crosspoint array to apply the first voltage;
a plurality of column switching devices disposed in a second doped semiconductor well and coupled to the second terminal, each of the plurality of column switching devices coupled to a corresponding column line in a plurality of column lines in the crosspoint array to apply the second voltage.

2. The decoder of claim 1, wherein in the crosspoint array is disposed on a semiconductor substrate comprising a first type of semiconductor, and the first doped semiconductor well and the second doped semiconductor well are disposed in the semiconductor substrate and each comprise a second type of semiconductor.

3. The decoder of claim 1, wherein the plurality of row switching devices comprises a first plurality of field effect transistors each having a bulk terminal comprising a portion of the first doped semiconductor well, and wherein the plurality of column switching devices comprises a second plurality of field effect transistors each having a bulk terminal comprising a portion of the second doped semiconductor well.

4. The decoder of claim 1, wherein the crosspoint array comprises a plurality of memory elements disposed at crossover points of the plurality of row lines and the plurality of column lines.

5. The decoder of claim 1, wherein the first doped semiconductor well comprises a terminal to couple to a third voltage and the second doped semiconductor well is coupled to the second terminal.

6. A method of decoding a crosspoint array, the method comprising:
addressing a selected memory element in a plurality of memory elements disposed in rows and columns in the crosspoint array by:
applying a drain voltage to a drain terminal of a field effect transistor switch for a selected row in the crosspoint array associated with the selected memory element;
biasing a bulk terminal of the field effect transistor switch for the selected row with a well voltage independent of a substrate voltage applied to a substrate in which the crosspoint array is disposed; and
driving a gate terminal of the field effect transistor switch for the selected row with a gate voltage comprising the drain voltage and the well voltage, wherein the drain voltage, the well voltage, and the gate voltage are selected to cause the field effect transistor switch for the selected row to operate as an ohmic switch.

7. The method of claim 6, wherein addressing the selected memory element further comprises:
applying the drain voltage to a gate terminal of a field effect transistor switch for a selected column in the crosspoint array associated with the selected memory element; and
applying a source voltage to a source terminal and a bulk terminal of the field effect transistor switch for the selected column.

8. The method of claim 7, wherein the field effect transistor switch for the selected row is disposed in a first doped semiconductor well and the field effect transistor switch for the selected column is disposed in a second doped semiconductor well.

9. The method of claim 6, wherein biasing the bulk terminal comprises biasing a doped semiconductor well in which the field effect transistor switch for the selected row is disposed.

10. The method of claim 8, further comprising biasing a bulk terminal of a field effect transistor switch for an unselected row with a voltage different from the well voltage.

11. The method of claim 8, further comprising sensing a voltage drop across the selected memory element.

12. A method comprising:
providing a crosspoint memory array comprising a plurality of memory elements disposed in a plurality of rows and plurality of columns;
forming a first plurality of field effect transistor switches disposed in a first doped semiconductor well to couple selectively the plurality of rows to a first voltage;
forming a second plurality of field effect transistor switches disposed in a second doped semiconductor well to couple selectively the plurality of columns to a second voltage.

13. The method of claim 12 wherein the plurality of memory elements comprises a plurality of resistive memory elements.

14. The method of claim 12, wherein the first doped semiconductor well comprises a plurality of doped semiconductor wells to allow biasing individually bulk terminals of subsets of the first plurality of field effect transistor switches.

15. The method of claim 12, wherein forming the first plurality of field effect transistor switches comprises forming at least one field effect transistor having a bulk comprising the first doped semiconductor well for each of the plurality of field effect transistor switches.
